(19) United States
(12) Patent Application Publication
(10) Pub. No.: US 2003/0059055 A1
(43) Pub. Date: Mar. 27, 2003

(54) Receiver, method, program and transport signal for adapting the sound volume of an acoustic signal of an incoming call

(76) Inventors: Laurent Lucat, Le Mans (FR); Gilles Miet, Le Mans (FR)

Correspondence Address: U.S. Philips Corporation, 580 White Plains Road, Tarrytown, NY, 10591, US

(21) Appl. No.: 10/196,050

(22) Filed: Jul. 15, 2002

(30) Foreign Application Priority Data
Jul. 17, 2001 (FR) 0109550

(51) Int. Cl. H04H 5/00; H04R 5/00; H03G 5/00

(52) U.S. Cl. 381/16; 381/1; 381/98; 381/17

(57) ABSTRACT

The invention relates to a communication receiver provided with spatialization means for generating a pseudo-stereophonic output signal from a monophonic input signal. The spatialization means comprise spectrum extension means for generating on a first output channel an output signal containing synthesis frequencies extrapolated from part of the original band of the monophonic input signal, while the input signal is sent over a second output channel.

The invention relates to a transmitter comprising spatialization means for generating a pseudo-stereophonic output signal from a monophonic input signal with a given spectral band referred to as the original band.

The invention also relates to a telephone receiver for receiving a signal, referred to as the input signal, with a given spectral band, referred to as the original band, comprising spatialization means for generating a pseudo-stereophonic output signal from said input signal.

The invention also relates to an audio spatialization method for generating a pseudo-stereophonic output signal from a monophonic input signal with a given spectral band referred to as the original band.

Finally, the invention relates to a computer program for implementing said method and a signal for transporting said computer program.

The invention has many applications, in particular in mobile telephones.

There are many methods, known as spatialization methods, for generating a pseudo-stereophonic signal from a monophonic signal, making it possible to differentiate, in an audio transmission apparatus, the right channel from the left channel. These methods can be classified in two main families, with on the one hand those which effect a spatial differentiation and on the other hand those which effect a phase differentiation.

It is an object of the invention to provide advantageous means for generating a pseudo-stereophonic signal from a monophonic signal according to a principle which combines a spectral differentiation and a phase differentiation.

For this purpose, a transmitter and a receiver of the type mentioned in the introductory paragraph are provided, characterized in that said spatialization means comprise spectrum extension means for generating a first output signal that contains synthesis frequencies extrapolated from part of the original band.

According to an important characteristic of the invention, the spectrum extension means comprise:

low-pass filtering means (245a) for selecting in the input signal a band of frequencies lower than a cutoff frequency,

first processing means (245b) for generating an intermediate signal comprising frequencies higher than the cutoff frequency, synthesized from frequencies of the selected band, and

second processing means (245c) for generating said first output signal by replacing in the input signal at least some of the frequencies of the original band higher than the cutoff frequency by said intermediate signal.

According to another characteristic of the invention, calculation means are provided for generating a second output signal, said second signal being a combination between the input signal and said first output signal in predetermined proportions.

The invention will be further described with reference to examples of embodiment shown in the drawings to which, however, the invention is not restricted.

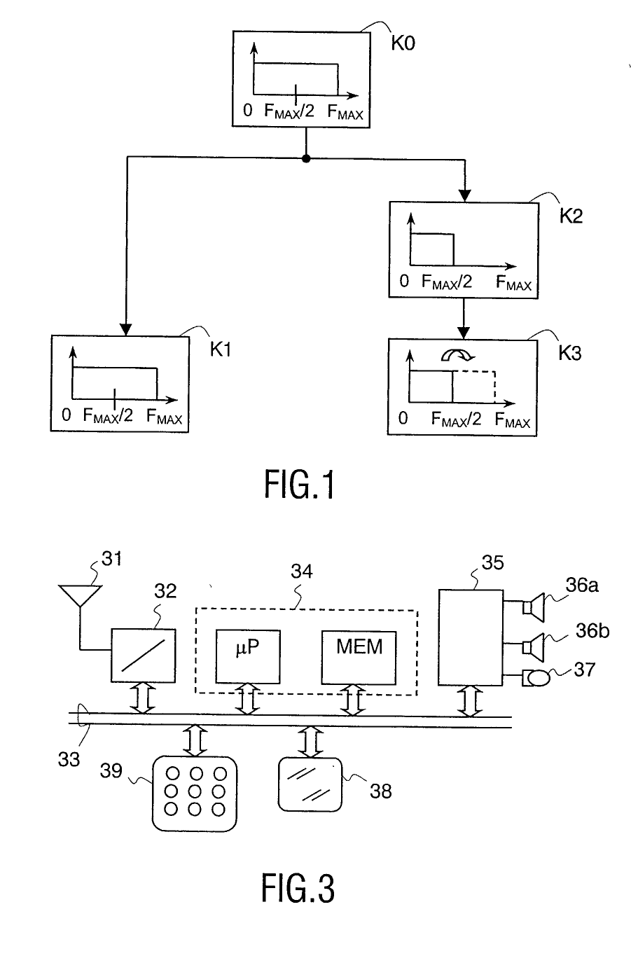

FIG. 1 is a functional block diagram for illustrating an example of a method according to the invention,

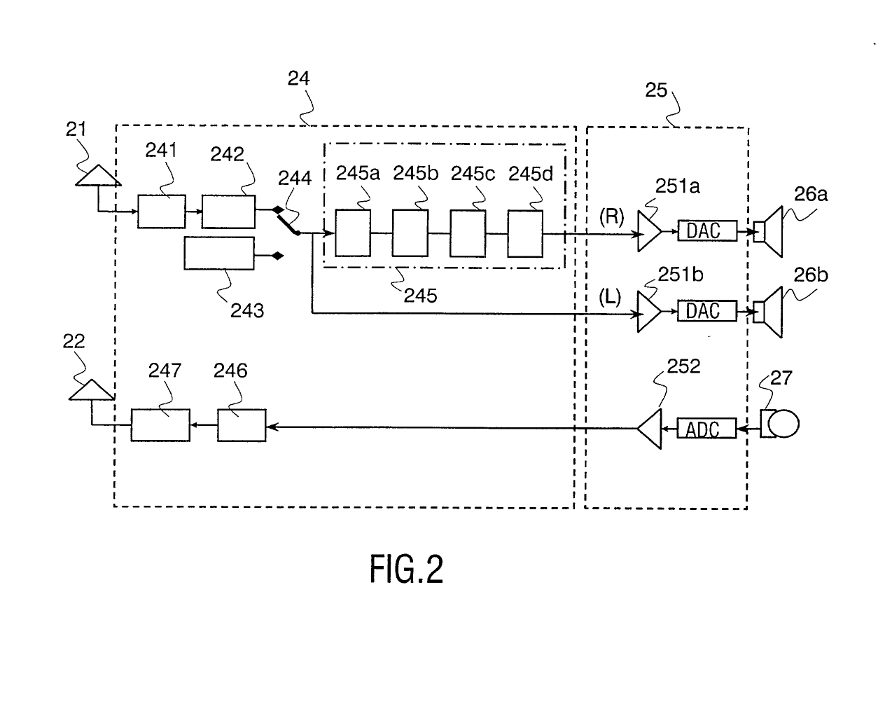

FIG. 2 is a functional block diagram representing a transceiver according to the invention,

FIG. 3 is a block diagram for illustrating an embodiment of a telephone receiver according to the invention.

FIG. 1 shows an example of embodiment of a method according to the invention for receiving an audio input signal with a given spectral band, referred to as the original band, comprising a spatialization step for generating a pseudo-stereophonic output signal from the input signal. According to the invention, the spatialization step comprises a filtering substep for filtering some of the frequencies of the original band and a spectrum extension substep for synthesizing synthesis frequencies extrapolated from the remaining frequencies of the original band.

The method is described below with reference to FIG. 1. It comprises the following steps:

a reception step KO for receiving a monophonic digital audio input signal with a given frequency spectrum between 0 and F_{MAX}=F_{S}/2, where Fₛ is the sampling frequency of the signal,

a step of recovering the input signal K1 in order to send it over a first output channel, for example over the left-hand channel of stereophonic headphones,

a filtering step K2 for eliminating some of the frequencies of the input spectrum, for example all the frequencies higher than the frequency F_{MAX}/2,

a spectrum extension step K3 for synthesizing new frequencies extrapolated from the frequencies remaining after filtering, with a view to obtaining a new composite signal consisting of part of the spectrum of the input signal to which a synthesized spectrum band has been added.

The audio input signal received at the reception step KO is a monophonic audio signal which can in particular contain music encoded, for example according to the digital MP3 format. This signal may be prerecorded from an original stereophonic signal, for the purpose of saving on memory space. It can also be an original monophonic signal received via a telecommunications system such as a mobile telephony system.

According to a preferred embodiment of the invention, the filtering step K2 performs a low-pass filtering at the cutoff frequency F_{MAX}/2. However, this is not limiting. In this case, the spectrum extension step K3 is provided for synthesizing the frequencies lying between F_{MAX}/2 and F_{MAX} from frequencies of the input signal lying between 0 and F_{MAX}/2.

Several variants of embodiment can be envisaged for obtaining a pseudo-stereophonic signal on two distinct audio output channels. According to a first variant, a first output signal corresponding to the input signal obtained at step K1 is sent over a first output channel of stereophonic headphones, for example the left-hand channel, and a second output channel consisting of the signal generated at step K3 is sent over a second channel, for example the right-hand channel. According to another variant, a first output signal identical to the input signal is sent over one of the audio output channels and a linear combination between the first signal and the signal generated at step K3 is sent over the other channel. By way of practical example, a linear combination consisting of 80% of the input signal and 20% of the signal synthesized at step K3 is sent over the right-hand channel while the input signal is sent over the left-hand channel.

The spectrum extension step K3 can use several known extension methods for synthesizing new frequencies from available initial frequencies. Many spectrum extension methods have been described for synthesizing, in reception mode, additional frequencies absent from the spectrum of the initially received signal with a view to improving the audio quality of the received signal. These methods find applications particularly in mobile telephony for obtaining a signal, referred to as broadband, in the band 70 Hz-8000 Hz, from a signal received in the traditional telephony band, referred to as narrow band, between 300 Hz and 3400 Hz.

The invention uses these spectrum extension methods not for effecting a posteriori extension of the spectral band of the received signal but for synthesizing a new signal containing new frequencies for replacing, in the input signal, frequencies initially present. This new synthesis signal is then sent over an audio output of stereo headphones while at the same time another signal, for example the non-processed input signal, is sent over the other output. In this way a pseudo-stereophonic signal has been produced from a monophonic signal. A method such as the one described in the internal patent application published under the number WO 01/35395 can be used in step K3 for synthesizing the high-pitched frequencies higher than F_{MAX}/2 from the band 0−F_{MAX}/2. Other methods can also be used, such as those described in:

American patent published under the number U.S. Pat. No. 5,581,652,

European patent application published under the number EP 0 911 807,

the journal “IEEE workshop on speech coding. Model, coders and error criteria, Porvoo, Finland, from Jun. 20 to 23, 1999”, pages 174-176, reference XP002159073, by J. Epps et al. “A new technique for wideband enhancement of coded narrowband speech”, etc.

FIG. 2 is a functional block diagram for illustrating the functioning of a telephone receiver according to the invention. It comprises a receiving antenna 21, a transmitting antenna 22, a digital signal processing unit 24, for example implemented by means of a processor of the DSP type (Digital Signal Processor), a coding/decoding audio unit 25, a pair of stereo earpieces 26a and 26b and a microphone 27. The coding/decoding audio unit 25 effects the analog to digital conversions ADC and digital to analog conversions DAC as well as the quantization of the signal thus digitized. The digital signal processing unit 24 comprises, for reception: a channel decoding unit 241, a source decoding unit 242, a unit for generating prerecorded monophonic music 243, for example coded according to the MP3 standard, a switch 244, a post-processing unit 245 and, for transmission: a source coding unit 246 and a channel coding unit 247.

According to a preferred embodiment of the invention illustrated in FIG. 2, the receiver can function according to two distinct modes at the choice of the user. According to the first mode, referred to as streaming mode, a pseudo-stereophonic signal is generated from a monophonic signal transmitted, for example, via a third-generation mobile telecommunication system and received via the receiving antenna 21 before being decoded by the channel decoding unit 241 and source decoding unit 242. According to the second mode, referred to as download mode, a pseudo-stereophonic signal is generated from a prerecorded monophonic signal, having been previously downloaded, for example from an Internet site and then stored in monophonic form in order to optimize memory space, with a view to being restored by the MP3 generation unit 243. The switch 244 is provided for connecting the input of the post-processing unit 245 to the output of the source decoding unit 242 or MP3 music generating unit 243, according to the mode chosen. The monophonic signal, referred to as the input signal, is then processed by the post-processing unit 245 according to the method described with reference to FIG. 1 for generating a distinct stereo signal on the left-hand channel (L) and on the right-hand channel (R), respectively. For this, the post-processing unit 245 comprises:

a low-pass filter 245a for selecting part of the original band containing the frequencies lower than the cutoff frequency F_{MAX}/2,

a first processing unit 245b for generating an intermediate signal comprising frequencies higher than the cutoff frequency, synthesized from frequencies of the band selected according to an appropriate spectrum extension method, and

a second processing unit 245c for generating a first output signal, replacing, in the input signal, at least some of the frequencies of the original band higher than the cutoff frequency, by the intermediate signal,

a calculation unit 245d for effecting a linear combination between the input signal and the first output signal according to predetermined proportions, for example 80% and 20% respectively, in order to obtain a second output signal intended to be sent over one of the output channels, for example the left-hand channel (L).

According to the embodiment described in FIG. 2, the left-hand channel (L) receives the input signal that has not been processed by the processing unit. According to variants of embodiment, the output signal sent over the left-hand channel can also undergo processing by the processing unit 245. This processing will then have to be different from the processing carried out on the right-hand channel so that the signals sent over the two channels are different to obtain the required pseudo-stereo effect. The calculation unit 245d is optional.

FIG. 3 is a diagram showing in block form the main components of the receiver described in FIG. 2. It comprises:

a transmitting/receiving antenna 31,

a transmission/reception unit 32,

a transport bus 33 for transporting addresses and data between the various components,

a digital signal processing unit 34 comprising in particular a microprocessor μP and memory MEM,

an audio interface 35 for connecting the circuits of the telephone with the loudspeakers of each channel 36a and 36b and the microphone 37,

a screen 38 and a keypad 39.

The digital signal-processing unit corresponds to the unit 24 in FIG. 2, and may be implemented by means of a DSP. The memory MEM comprises random access memory for storing temporary data and read only memory for storing permanent data such as program code instructions intended to implement the method described in FIG. 1. The interface 35 corresponds to the audio coding/decoding unit 25 of FIG. 2.

The monophonic audio signal is either received by the antenna 31 and then converted by the reception circuits 32 before being processed in the digital processing unit 34, or supplied directly by the digital processing unit 34, in which it was stored in memory. After separation into two distinct signals and specific processing of each of the signals, each signal is converted into an analog signal by the interface unit 35 in order to be sent over a distinct output channel of a stereo headset depicted in FIG. 3 by the loudspeakers 36a and 36b.

A transmitter, receiver, method, computer program and signal for generating a pseudo-stereo signal from a mono signal have thus been described and illustrated by means of examples. Other examples of embodiment can easily be derived from the examples described without departing from the scope of the invention. In particular, the invention is not limited to the spectrum extension methods cited.

1. A transmitter comprising spatialization means for generating a pseudo-stereophonic output signal from a monophonic signal referred to as the input signal with a given spectral band referred to as the original band, characterized in that said spatialization means comprise spectrum extension means (245) for generating a first output signal that contains synthesis frequencies extrapolated from part of the original band.

2. A transmitter as claimed in claim 1, in which said spectrum extension means comprise:
low-pass filtering means (245a) for selecting in the input signal a band of frequencies lower than a cutoff frequency,
first processing means (245b) for generating an intermediate signal comprising frequencies higher than the cutoff frequency, synthesized from frequencies of the selected band, and
second processing means (245c) for generating said first output signal by replacing in the input signal at least some of the frequencies of the original band higher than the cutoff frequency by said intermediate signal.

3. A transmitter as claimed in claim 2, comprising calculation means (245d) for generating a second output signal, said second signal being a linear combination between the input signal and said first output signal in predetermined proportions.

4. A telephone receiver for receiving a signal, referred to as the input signal, with a given spectral band, referred to as the original band, and spatialization means for generating a pseudo-stereophonic output signal from said input signal, characterized in that said spatialization means comprise spectrum extension means (245) for generating a first output signal containing synthesis frequencies extrapolated from part of the original band.

5. A receiver as claimed in claim 4, in which said spectrum extension means comprise:
low-pass filtering means (245a) for selecting in the input signal a band of frequencies lower than a cutoff frequency,
first processing means (245b) for generating an intermediate signal comprising frequencies higher than the cutoff frequency, synthesized from frequencies of the selected band, and
second processing means (245c) for generating said first output signal by replacing in the input signal at least some of the frequencies of the original band higher than the cutoff frequency by said intermediate signal.

6. A receiver as claimed in claim 5, comprising calculation means (245d) for generating a second output signal, said second signal being a linear combination between the input signal and said first output signal in predetermined proportions.

7. An audio spatialization method for generating a pseudo-stereophonic output signal from a monophonic input signal with a given spectral band referred to as the original band, characterized in that it comprises a filtering step (K2) for selecting some of the frequencies of the original band and a spectrum extension step (K3) for synthesizing extrapolated frequencies from selected frequencies.

8. A computer program containing program code instructions for implementing the method as claimed in claim 7.

9. A signal for transporting a computer program as claimed in claim 8.
